(19) United States
(12) Patent Application Publication
(10) Pub. No.: US 2021/0349245 A1
(43) Pub. Date: Nov. 11, 2021

(54) OPTICAL MEMBER AND IMAGE DISPLAY DEVICE

(71) Applicant: NITTO DENKO CORPORATION, Ibaraki-shi, Osaka (JP)

(72) Inventors: Takanobu Yano, Ibaraki-shi, Osaka (JP); Yoshitaka Sugita, Ibaraki-shi, Osaka (JP); Masayoshi Katagiri, Ibaraki-shi, Osaka (JP)

(73) Assignee: NITTO DENKO CORPORATION, Ibaraki-shi, Osaka (JP)

(21) Appl. No.: 17/282,869

(22) PCT Filed: Jun. 11, 2019
(86) PCT No.: PCT/JP2019/023162

§ 371 Date: Apr. 5, 2021

(30) Foreign Application Priority Data
Oct. 16, 2018 (JP) 2018-195385

(51) Int. Cl. G02B 5/30; H05B 33/24; H01L 51/52; G06F 3/041

(52) U.S. Cl. CPC G02B 5/30; G06F 3/0412; H01L 51/5237; H05B 33/24

(57) ABSTRACT

An optical member is arranged on a viewer-side of an image display panel. The optical member includes a circular polarizing plate having a first principal surface and a second principal surface, and a patterned light reflection layer arranged on a first principal surface-side of the circular polarizing plate. The circular polarizing plate is configured such that light incident from a second principal surface-side to a first principal surface-side is emitted as circular polarized light. The light reflection layer has a light-shielding property, and is configured to reflect light from a circular polarizing plate-side with fixed-end reflection.

### TECHNICAL FIELD

The present invention relates to an optical member arranged on a of an image display device. The present invention also relates to an image display device having the optical member.

### BACKGROUND ART

In an image display device such as a liquid crystal display device and an organic EL display device, a pattern decorative layer having a frame shape such that a drive element and a lead-out wiring of a touch panel arranged on an outer periphery of a display unit are not visually recognized from the outside. For example, the pattern decorative layer is disposed by a method of printing a decorative pattern on a cover window disposed a front surface of the image display device or by laminating a transparent film on which a decorative pattern is printed.

It is necessary for the decorative layer not to reflect light from a viewer-side in addition to shielding light from an image display panel-side. In order to reduce a transmittance and a reflectance, the decorative layer is generally formed by printing black ink with a thickness of several micrometers to several tens of micrometers (for example, Patent Document 1). Patent Document 2 discloses a decorative layer in which a metal thin-film and an ink layer are stacked.

### PRIOR ART DOCUMENTS

### Patent Documents

Patent Document 1: Japanese Unexamined Patent Publication No. 2014-725

Patent Document 2: Japanese Unexamined Patent Publication No. 2011-194799

### SUMMARY OF THE INVENTION

### Problems to be Solved by the Invention

When a cover window or a decorative film on which a pattern decorative layer is provided is attached to another member via a pressure sensitive adhesive, it is difficult for a pressure sensitive adhesive to fill a printing level difference portion, and visibility caused by mixing air bubbles is reduced or problems such as peeling may occur. Thus, it is necessary to provide level difference-absorbing property by increase a thickness of an pressure sensitive adhesive layer, and thinning of a display device is hindered. When the decoration printing has a large thickness, bending resistance and folding resistance of the decorative layer are not sufficient, and it is difficult to apply the decorative layer to a flexible display or a foldable display.

Since a metal thin-film has high light-shielding property, it is possible to shield the light from an image display panel-side even with a small thickness. However, when the pattern decorative layer is formed only by the metal thin-film, since the light (external light) from a viewer-side is reflected by the metal thin-film of a pattern forming portion and is visually recognized, visuality is inferior. In order to reduce the reflection of the light from the viewer-side, it is necessary to reduce the reflection of the light by the metal thin-film by stacking a printed ink layer on the viewer-side of the metal thin-film, and it is difficult to sufficiently reduce a thickness of the pattern forming portion.

In view of the above, it is an object of the present invention to provide an optical member which has high light-shielding property and is difficult for reflected light at pattern forming portion to be visually recognized from outside even when a thickness of a pattern forming portion is small.

### Means for Solving the Problems

An optical member of the present invention has a configuration in which a patterned light reflection layer is disposed on a first principal surface-side of a circular polarizing plate. The light reflection layer has, for example, a frame-like pattern in a plan view. A touch panel may be disposed on the light reflection layer on a side opposite to the circular polarizing plate-side.

The circular polarizing plate is configured to emit, as circular polarized light, light incident from a second principal surface-side to the first principal surface-side. The light reflection layer has light-shielding property. The light reflection layer reflects light from the circular polarizing plate-side with fixed-end reflection. Examples of a material that reflects light with fixed-end reflection include metal material and high refractive index materials.

The light reflection layer preferably includes a metal layer. A thickness of the light reflection layer is preferably 3 μm or less. The light reflection layer may be integrally stacked with the circular polarizing plate directly or via another layer.

The present invention relates to an image display device in which the above optical member is disposed on a front surface of the image display panel on a viewer-side. A cover window may be provided on a front surface of the optical member on the viewer side. The image display panel is, for example, an organic EL panel. The image display device may be configured to be bendable and/or foldable.

### Effects of the Invention

In the above configuration, since the light reflection layer is arranged in the decorative pattern portion, the light-shielding property of the light from the image display panel-side is excellent, so that drive element, lead-out wiring, and the like can be prevented from being visually recognized from the outside. Since the circular polarizing plate is disposed on the viewer-side of the light reflection layer, the external light reflected by the light reflection layer is absorbed by the circular polarizing plate, and since the reflected light is hardly visually recognized from the outside, visuality is excellent. In this configuration, since the thickness of the decorative pattern portion can be reduced, it can be easily applied to a flexible display, a foldable display, or the like.

### BRIEF DESCRIPTION OF THE DRAWINGS

FIG. 1 is a cross-sectional view of a configuration of an optical member having a patterned reflection layer on a circular polarizing plate.

FIG. 2 is a plan view of an optical member of FIG. 1.

FIG. 3 is a schematic cross-sectional view illustrating a configuration example of an image display device.

FIG. 4 is a schematic cross-sectional view illustrating a configuration example of the image display device.

FIG. 5 is a schematic cross-sectional view illustrating a configuration example of the image display device.

### MODE FOR CARRYING OUT THE INVENTION

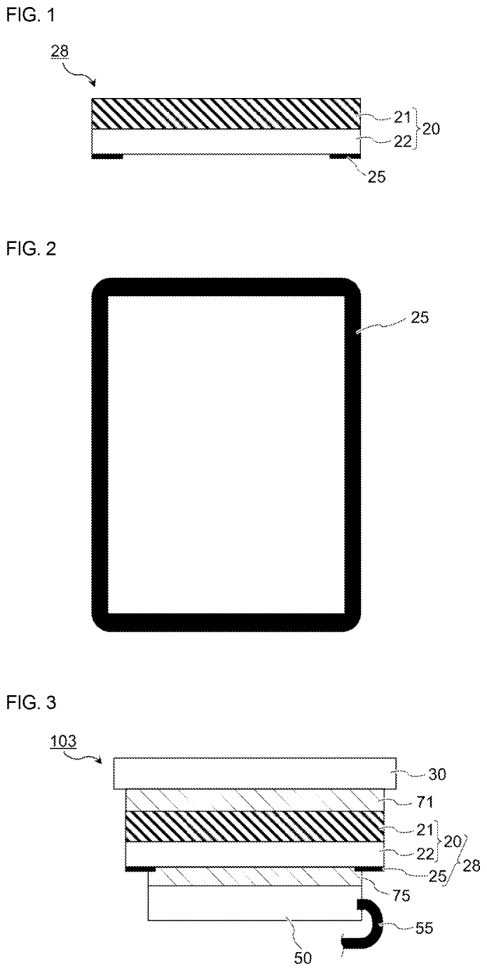

FIG. 1 is a cross-sectional view of a configuration of a light reflection layer-equipped circular polarizing plate, which is one embodiment of an optical member of the present invention. FIG. 2 is a plan view of the light reflection layer-equipped circular polarizing plate 28 of FIG. 1 as viewed from a light reflection layer 25-side. FIG. 3 is a cross-sectional view of a configuration of an image display device 103 in which the light reflection layer-equipped circular polarizing plate 28 is disposed on an organic EL panel 50 and a cover window 30 is disposed on the circular polarizing plate.

The circular polarizing plate converts light incident from one surface into circular polarized light and emits the circular polarized light to the other surface. In the embodiment illustrated in FIG. 1, a quarter wave plate 22 is stacked on a first principal surface of a polarizer 21. An absorption axis direction of the polarizer 21 and a slow axis direction of the quarter wave plate 22 are arranged so as to form at an angle of approximately 45°, and thus, the polarizer 21 and the quarter wave plate 22 constitute a circular polarizing plate 20. Light incident on the circular polarizing plate 20 from a second principal surface-side (upper side in the drawings) becomes linear polarized light by being absorbed by the polarizer 21 in the absorption axis direction. The linear polarized light emitted from the polarizer 21 is converted into circular polarized light by the quarter wave plate 22.

The light reflection layer 25 having a frame-like pattern is provided on a first principal surface of the quarter wave plate 22, and a second principal surface of the light reflection layer 25 faces the first principal surface of the quarter wave plate 22 (a first principal surface of the circular polarizing plate 20). The light reflection layer 25 has a light-shielding property. The second principal surface of the light reflection layer 25 (a surface facing the quarter wave plate 22) has light-reflecting property and reflects light from the quarter wave plate 22-side with fixed-end reflection.

In the image display device 103 illustrated in FIG. 3, a flexible printed circuit (FPC) 55 is connected to an end of the organic EL panel 50. The FPC 55 is bent so as to wrap around a rear-side of the organic EL panel 50. In the image display device 103, since the light reflection layer 25 having light-shielding property is provided on a viewer-side of the organic EL panel 50, the FPC 55 is not visually recognized to a viewer of the image display device. Light (image light) from the organic EL panel 50 is generally unpolarized light, and is transmitted through the quarter wave plate 22 constituting the circular polarizing plate 20. Light that vibrates in the absorption axis direction is absorbed by the polarizer 21. The light vibrating in a transmission axis direction of the polarizer 21 is not absorbed by the polarizer 21 and reaches the viewer through the cover window 30.

When external light is incident from the viewer-side (cover window 30) of the image display device 103, the light transmitted through the polarizer 21 and the quarter wave plate 22 in order from the second principal surface-side of the circular polarizing plate 20 is emitted as circular polarized light to the first principal surface-side (lower side of the drawings). Since the second principal surface of the light reflection layer 25 has light-reflecting property, the circular polarized light emitted from the circular polarizing plate 20 is reflected to the circular polarizing plate 20-side by the light reflection layer 25. Since the light reflection by the light reflection layer 25 is fixed-end reflection, a phase shifts by π during the reflection, and the reflected light becomes reversed circular polarized light. This reversed circular polarized light is incident on the quarter wave plate 22 again and is converted into linear polarized light. Since a vibration direction of this linear polarized light is perpendicular to the transmission axis direction of the polarizer 21 (parallel to the absorption axis direction of the polarizer 21), the linear polarized light is absorbed by the polarizer 21. That is, since the external light reflected by the second principal surface of the light reflection layer 25 is absorbed by the polarizer 21 and the reflected light does not reach the viewer-side, reflectance is substantially zero. Thus, the light reflection layer 25 looks black when this light reflection layer is visually recognized through the circular polarizing plate 20.

As described above, the light reflection layer 25 having light-shielding property is disposed, and thus, the FPC 55, etc. disposed under the light reflection layer 25 is not visually recognized from the outside. Since the circular polarizing plate 20 is disposed on the viewer-side of the light reflection layer 25 and light is reflected on the second principal surface of the light reflection layer 25 with fixed-end reflection, the reflected light from the light reflection layer 25 is absorbed by the polarizer 21, and the light reflection layer 25 is visually recognized in black. Since such a material having light-reflecting property (typically, metal) has a smaller thickness and higher light-shielding property than a black material such as black ink containing a pigment or the like, the thickness of the light reflection layer 25 can be reduced.

In an organic EL display device, since a thickness of a light emitting layer is extremely as thin as about 10 nm, the external light is transmitted through the light emitting layer and reaches a metal electrode (rear electrode), and the external light reflected by the metal electrode is emitted to the viewer-side again. Thus, when the organic EL display device is viewed from the outside, a screen looks like a mirror surface. The circular polarizing plate is disposed on the viewer-side of the organic EL panel, and thus, the visibility and visuality of the screen can be improved by shielding the reflected light from the metal electrode. As the circular polarizing plate 20 disposed on the viewer-side of the light reflection layer 25, the circular polarizing plate for shielding the reflected light from the metal electrode of the organic EL panel can be applied as it is. Accordingly, in the image display device having the circular polarizing plate 20 on a front surface of the organic EL panel 50 on the viewer-side, the above operation can be realized only by adding the light reflection layer 25 between the organic EL panel 50 and the circular polarizing plate 20.

The configuration of the circular polarizing plate 20 is not particularly limited as long as the circular polarizing plate emits, as the circular polarized light, the light incident from the second principal surface-side to the first principal surface-side. The circular polarizing plate has typically the quarter wave plate 22 stacked on the first principal surface of the polarizer 21 as illustrated in FIG. 1.

Examples of the polarizer 21 include films obtained by uniaxially stretching a hydrophilic polymer film such as a polyvinyl alcohol-based film, a partially formalated polyvinyl alcohol-based film or an ethylene-vinyl acetate copolymer-based partially saponified film with a dichroic substance such as iodine or a dichroic dye adsorbed to the film, and polyene-based oriented films such as dehydrated products of polyvinyl alcohol and dehydrochlorinated products of polyvinyl chloride.

A transparent film (not illustrated) may be laminated on one surface or both surfaces of the polarizer 21 as a polarizer protective film. As a material for the transparent film, one having excellent transparency, mechanical strength, thermal stability, moisture barrier property and optical isotropy, such as a cellulose-based resin, a cyclic polyolefin-based resin, an acryl-based resin, a phenylmaleimide-based resin or a polycarbonate-based resin, is preferably used.

The stacking configuration of the quarter wave plate 22 on the first principal surface of the polarizer 21 is not particularly limited. A polarizer protective film may be attached to a front surface of the polarizer 21, and the quarter wave plate may be stacked via the polarizer protective film. The quarter wave plate 22 which also functions as the polarizer protective film may be directly attached to the polarizer 21. The polarizer 21 and the quarter wave plate 22 may not be integrally stacked, and may be arranged apart from each other.

A retardation of the quarter wave plate and an angle between the absorption axis direction of the polarizer and the slow axis direction of the quarter wave plate may be within a range in which the linear polarized light emitted from the polarizer is converted into substantially circular polarized light. The “substantially circular polarized light” may include not only complete circular polarized light but also elliptical polarized light close to the complete circular polarized light, that is, having an ellipticity close to 1. For example, a quarter wave plate having a retardation range of 137.5±30 nm at a wavelength of λ=550 nm is also included in the “quarter wavelength”. The retardation of the quarter wave plate at a wavelength of 550 nm is preferably 137.5±20 nm, more preferably 137.5±10 nm. The fact that the angle formed by the absorption axis direction of the polarizer and the slow axis direction of the quarter wave plate is approximately 45° means a range of approximately 35° to 55°, preferably 40° to 50°, more preferably 43° to 47°, more preferably 44° to 46°.

The quarter wave plate 22 may be a stacked body of two or more films. For example, a plurality of films having different wavelength dispersions of the retardation is stacked such that the wavelength dispersion of the retardation of the quarter wave plate is adjusted to obtain wide-band circular polarizing plate. Viewing angle dependence may be reduced by stacking the plurality of films to adjust three-dimensional refractive index anisotropy (refractive index ellipsoid).

A visible light transmittance of the light reflection layer 25 provided on the first principal surface-side of the circular polarizing plate 20 is preferably 1% or less, more preferably 0.5% or less, further preferably 0.1% or less. Since the visible light transmittance of the light reflection layer 25 is low and the light-shielding property thereof is high, the light reflection layer 25 functions as a “blind layer”, and thus, a wiring or the like provided under the light reflection layer 25 can be prevented from being visually recognized from the outside.

A visible light reflectance of the light reflection layer 25 is preferably 30% or more, more preferably 40% or more, further preferably 50% or more. As the visible light reflectance of the light reflection layer 25 becomes higher, the reflectance tends to become lower when the light reflection layer is visually recognized through the circular polarizing plate 20, and thus, visuality is excellent.

As described above, in order for the circular polarized light from the circular polarizing plate 20 to be reflected by the light reflection layer 25 and then absorbed by the polarizer 21 of the circular polarizing plate 20, the light reflection on the second principal surface of the light reflection layer 25 needs to be fixed-end reflection, and the reflected light needs to be reversed circular polarized light by shifting by n during the reflection. When the light reflection layer 25 has metallic glare, since the reflection by the light reflection layer 25 is fixed-end reflection, the reflected light is reversed circular polarized light.

Typical examples of materials having metallic glare are other metals such as Au, Ag, Cu, Al, Pt, Ti, V, Cr, Mn, Fe, Co, Ni, Zn, Ga, Ge, Zr, Nb, Mo, Tc, Ru, Rh, Pd, In, Sn, Sb, Hf, Ta, W, Re, Os, Ir, Ti, and Bi. The metal material may be an alloy of a plurality of metallic elements.

A paste material containing metal fine particles in a resin binder may be used as the material of the light reflection layer 25. The light reflection layer 25 may have a multi-layer configuration. For example, different types of metal layers may be stacked. The light reflection layer 25 may be a stacked metal layer and another layer. For example, in order to improve adhesion between a metal layer and a resin film, a primer layer made of a metal compound such as a metal oxide, a metal nitride, a metal carbide, a metal sulfide, or a resin material may be provided. When the primer layer is provided between the metal layer and the quarter wave plate, it is preferable that optical influence can be ignored so as not to interfere with the light reflection (fixed-end reflection) in the metal layer. Specifically, it is preferable that the primer layer provided between the metal layer and the quarter wave plate is light transmissive. When the primer layer has light-shielding property (light-absorbing property), it is preferable that the primer layer has a small thickness enough not to affect optical effects. For example, the primer layer has a thickness of 500 nm or less, 300 nm or less, 100 nm or less, 50 nm or less, or 30 nm or less.

Even though the material does not have metallic glare, when light from a medium having a relatively low refractive index is reflected by a medium having a relatively high refractive index (light reflection layer), the reflection is fixed-end reflection. For example, when the light reflection layer 25 is arranged in contact with the first principal surface of the quarter wave plate 22 and when a refractive index of the light reflection layer 25 is higher than a refractive index of the quarter wave plate 22, the light reflection on the second principal surface of the light reflection layer 25 is fixed-end reflection. When the light reflection layer 25 does not contain a metal material, it is preferable that the light reflection layer 25 has a high refractive index in order to increase a reflectance at an interface. In the light reflection layer containing no metal material, a refractive index of the second principal surface is preferably 1.8 or more, more preferably 2.2 or more, further preferably 2.5 or more.

A material which does not perform fixed-end reflection is not suitable as the material of the light reflection layer 25, even though the material has light-reflecting property. For example, white paper has a high visible light reflectance, but is not suitable as the material of the light reflection layer in the optical member of the present invention since the light reflection thereon is not fixed-end reflection.

Considering thinning of an image display device and bending resistance, etc. in application to a flexible display and a foldable display, the thickness of the light reflection layer 25 is preferably 3 μm or less, more preferably 1 μm or less, and further preferably 500 nm or less. From the viewpoint of attaining sufficient light-shielding property, the thickness of the light reflection layer 25 is preferably 10 nm or more, more preferably 30 nm or more, further preferably 50 nm or more.

It is preferable that the light reflection layer 25 is a metal thin-film due to high reflectance and excellent light-shielding property even with a small thickness. The metal thin-film can be formed by a dry process such as a sputtering method, a vacuum vapor deposition method, a CVD method, or an electron beam deposition method. The metal thin-film may be formed by electrolytic plating or electroless plating. As described above, the primer layer or the like may be provided on a front surface of the metal thin-film in order to improve adhesion or the like.

As illustrated in FIG. 2, the light reflection layer 25 is patterned in a frame shape in a plan view. An opening may be provided in the light reflection layer in an installation portion of a camera, a sensor, or the like. In an image display device, an area surrounded by the light reflection layer having frame shape is an image display area (screen). In an image display device having a touch panel sensor, an area surrounded by the light reflection layer having frame shape is an image display area and becomes a position detection area. The pattern shape of the light reflection layer is not limited to frame shape, and may be appropriately designed according to a shape of the image display device, a shape of the area to be decorated (or blinding wiring, etc.), and the like.

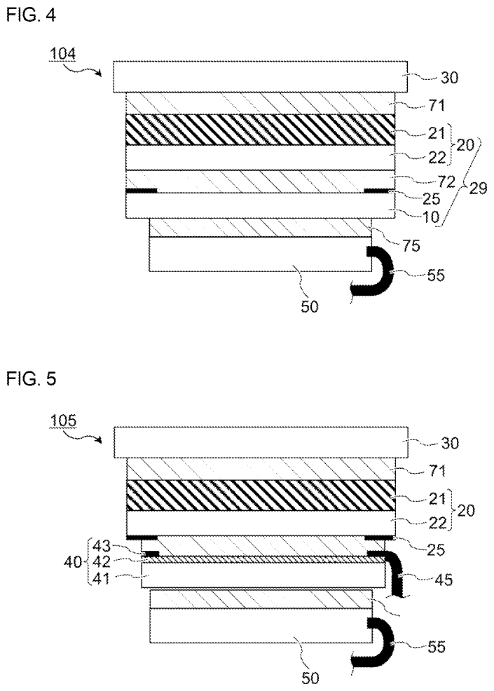

FIGS. 1 and 3 illustrate an example in which the light reflection layer 25 is arranged in contact with the first principal surface of the circular polarizing plate 20. The light reflection layer may be disposed between the image display panel and the circular polarizing plate, and may not be arranged in contact with the circular polarizing plate. For example, as in an image display device 104 illustrated in FIG. 4, a decorative film having the patterned light reflection layer 25 on a transparent substrate 10 may be integrally stacked with the circular polarizing plate 20 via an pressure sensitive adhesive layer 72. The light reflection layer may be provided on a surface of the transparent substrate 10 on the organic EL panel 50-side. The light reflection layer may be provided on the substrate on the front surface of the organic EL panel on the viewer-side.

The cover window 30 may be disposed on the front surface of the circular polarizing plate 20 on the viewer-side. The cover window 30 plays a role of preventing damage of the image display panel due to an impact from an outer front surface and preventing intrusion of wind, rain, dust, or the like from the outside. A transparent member having an appropriate mechanical strength and thickness is used as a material of the cover window 30. For example, a transparent resin substrate such as an acrylic resin or a polycarbonate resin, a glass substrate, or the like is used as the transparent member constituting the cover window. In flexible displays and the foldable displays, a flexible transparent resin substrate such as transparent polyimide is used. A foldable thin glass substrate may be used as the cover window. An anti-reflection layer, a hard coat layer, or the like may be provided on the front surface of the cover window 30 on the viewer-side.

The cover window 30 may be integrally stacked with the circular polarizing plate 20 via an pressure sensitive adhesive layer 71. Since the light reflection layer provided on the first principal surface-side of the circular polarizing plate 20 has light-shielding property and is configured such that the wiring and the like are not visually recognized from the outside, the cover window 30 may not have a decorative layer. When the cover window 30 does not have the decorative layer, since it is not necessary to provide step-absorbing property to the pressure sensitive adhesive layer 71 used for attaching the cover window 30, a thickness of the pressure sensitive adhesive layer 71 can be reduced, and thus, it is advantageous to reduce the thickness of the display device.

The organic EL panel 50 has a stacking structure in which an organic light emitting layer is sandwiched between a pair of electrodes. In addition to the light emitting layer, an organic layer such as a charge transport layer may be provided between the pair of electrodes. A stack of these layers is formed on the substrate. A transparent substrate such as glass or a transparent film is used in a bottom emission type organic EL panel that extracts light from the substrate-side. The substrate of the top emission type organic EL panel may be transparent or non-transparent. A backplane in which a driving element such as a TFT is mounted is generally provided on a rear-side of the organic EL panel. In addition, a barrier layer, a cushion material, or the like may be disposed.

The image display panel is not limited to the organic EL panel, and may be a liquid crystal panel, a plasma panel, or the like. When the image display panel is a liquid crystal panel, a polarizing plate is provided on a viewer-side of a liquid crystal cell. The polarizing plate on a front surface of the liquid crystal cell on the viewer-side may be omitted and substituted to the polarizer 21 of the circular polarizing plate 20 on the viewer-side. For example, a retarder may be disposed between the liquid crystal cell and the light reflection layer 25, and appropriate optical compensation may be performed by combining the retarder and the quarter wave plate constituting the circular polarizing plate 20.

The image display device may include a touch panel. An image display device 105 illustrated in FIG. 5 includes the light reflection layer 25 on the first principal surface-side of the circular polarizing plate 20, and a touch panel 40 is disposed between the organic EL panel 50 and the light reflection layer 25.

The touch panel 40 includes a transparent conductive layer 42 on a transparent substrate 41, and a metal lead-out wiring 43 is provided on an outer periphery thereof. Examples of a material of the transparent conductive layer 42 include conductive oxides such as indium tin oxide (ITO) and metal nanowires. The transparent conductive layer 42 may be patterned in various shapes. For example, in a projected capacitive touch panel, the transparent conductive layer is patterned in a striped shape or a square shape. Although FIG. 5 illustrates a mode in which the transparent conductive layer 42 is provided on one side of one transparent substrate 41, the projected capacitive touch panel generally has two transparent conductive layers, and positions in X and Y directions are detected on the transparent conductive layers.

The lead-out wiring 43 is a wiring formed by using a metal paste electrode or a sputtered metal film, and the FPC 45 is connected to the lead-out wiring 43. When the light reflection layer 25 is arranged in an area where the lead-out wiring 43 and the FPC 45 are provided, the lead-out wiring 43 and the FPC 45 are not visually recognized to the viewer of the image display device.

In the image display device 105 illustrated in FIG. 5, the touch panel 40 is provided between the circular polarizing plate 20 and the organic EL panel 50. In this configuration, since the reflected light from the transparent conductive layer 42 is also hardly visually recognized, there is an advantage that a pattern boundary of the patterned transparent conductive layer is hardly visually recognized from the outside.

An appropriate pressure sensitive adhesive layer is suitably used for stacking the circular polarizing plate 20 and the decorative film with the touch panel, or the like. An appropriate pressure sensitive adhesive layer is also suitably used for stacking the image display panel and the optical member. One having a high visible light transmittance is suitably used as the pressure sensitive adhesive layer. For example, an acrylic pressure sensitive adhesive layer has excellent optical transparency, exhibits appropriate wettability, cohesiveness and adhesiveness, and has excellent weather resistance and heat resistance. The thickness of the pressure sensitive adhesive layer 71, 72, or 73 is generally about 5 to 300 μm, preferably about 10 to 200 μm.

The order of manufacturing the image display device is not particularly limited, and the touch panel, the decorative film, the circular polarizing plate, the cover window, and the like may be sequentially stacked on the image display panel. The optical member 28 or 29 including the circular polarizing plate 20 and the light reflection layer 25 may be formed in advance, and the optical member may be disposed on the image display panel. The touch panel may be integrally stacked with the optical member. As described above, when the touch panel is disposed, the circular polarizing plate 20, the light reflection layer 25, and the touch panel 40 may be stacked in this order from the viewer-side.

When the decorative layer is formed with black ink, since the thickness of the decorative layer is large, it is necessary to impart level difference-absorbing property by softening the pressure sensitive adhesive layer arranged in contact with the decorative layer and increasing the thickness thereof. In the configuration of the present invention, since a thickness of a decorative pattern forming portion can be reduced by forming a decorative pattern by the light reflection layer 25, the pressure sensitive adhesive layer may not have level difference-absorbing property. Thus, the thickness of the pressure sensitive adhesive layer in contact with the light reflection layer 25 can be reduced, and it is advantageous to reduce the thickness of the image display device. The thickness of the light reflection layer 25 forming the decorative pattern is small, and thus, the light reflection layer is hardly cracked or peeled even when the optical reflection layer is bent or folded repeatedly. Accordingly, the configuration of the present invention is also suitable for application to flexible display and foldable display.

### Examples

The present invention will be described in more detail below by illustrating evaluation results of various films and materials having light-reflecting property, but the present invention is not limited to the following examples.

[Preparation of Evaluation Film]

In Examples 1 to 3, a metal thin-film (Al, Nb, or Ag) having a thickness of 120 nm was formed as a decorative layer on an optically isotropic film having a thickness of 40 μm (“ZeonorFilm ZF-16” manufactured by Zeon Corporation) by magnetron sputtering. In Comparative Example 1, a silicon thin-film was formed on an optically isotropic film instead of the metal thin-film. In Comparative Example 2, a decorative film in which a black ink layer having a thickness of 6 μm was printed on an optically isotropic film was used. In Comparative Example 3, a decorative film in which a black ink layer having a thickness of 12 μm was printed on an optically isotropic film was used. In Comparative Example 4, white thick paper (380 μm) having a glare-treated surface was used.

[Preparation of Stacked Body of Circular Polarizing Plate and Evaluation Film]

On one surface of a polarizing plate in which a transparent protective film is provided on both sides of a 25 μm-thick polarizer made of a stretched iodine-impregnated polyvinyl alcohol film, a quarter wave plate made of a polymer stretched film is laminated via an acrylic pressure sensitive adhesive layer to obtain a circular polarizing plate. An absorption axis direction of the polarizer and a slow axis direction of the quarter wave plate were arranged so as to form 45°. The circular polarizing plate and the above evaluation film are laminated via an acrylic pressure sensitive adhesive, such that the quarter wave plate-side surface of the circular polarizing plate and the decorative layer-formed surface (a surface of thick paper in Comparative Example 4) of the above evaluation film are facing each other, to obtain a stacked body.

[Measurement of Visible Light Transmission and Reflection Spectrum]

A transmission spectrum and a reflection spectrum of visible light of the above evaluation film and the above stacked body were measured by using a spectrophotometer (“U-4100” manufactured by Hitachi High-Tech). As for the reflected light, light was incident from the decorative layer-side (the circular polarizing plate-side for the stacked body with the circular polarizing plate) at an incident angle of 5°, and an absolute reflectance of the light reflected at 5° was measured. A visual transmittance (or visual reflectance) Y and hues a″ and b″ of L″a″b″ color system were calculated from the obtained transmission spectrum and reflection spectrum.

Table 1 shows the configurations of the decorative layers in the evaluation films of Examples and Comparative Examples, and the evaluation results of the transmitted light and the reflected light of the evaluation films (simple substance) and the stacked bodies with the circular polarizing plate.

TABLE 1

| | | | | Transmitted light | | | | | | Reflected light | | | | | |
|---|---|---|---|---|---|---|---|---|---|---|---|---|---|---|---|
| | | | | | | | Stacked body with | | | | | | Stacked body with | | |
| | Configuration of | | | | | | circular polarizing | | | | | | circular polarizing | | |
| | decorative layer | | | Decorative film only | | | plate | | | Decorative film only | | | plate | | |
| | material | thickness | | Y | a* | b* | Y | a* | b* | Y | a* | b* | Y | a* | b* |
| Example 1 | Al | 120 | nm | 0.01 | −0.06 | 0.03 | 0.01 | −0.06 | 0.04 | 87.79 | −0.51 | −1.35 | 4.94 | 0.55 | −0.75 |
| Example 2 | Nb | 120 | nm | 0.06 | 0.17 | 0.51 | 0.05 | 0.08 | 0.43 | 43.84 | 0.61 | 3.16 | 4.68 | 0.48 | −0.49 |
| Example 3 | Ag | 120 | nm | 0.02 | 0.06 | −0.41 | 0.02 | −0.03 | −0.18 | 93.66 | −0.75 | 3.16 | 5.01 | 0.34 | −0.55 |
| Comparative | Si | 120 | nm | 20.66 | −1.57 | 33.01 | 13.88 | −0.71 | 33.24 | 35.35 | 15.23 | 16.74 | 4.78 | 1.07 | 0.44 |
| Example 1 | | | | | | | | | | | | | | | |
| Comparative | Black ink | 6 | μm | 0.86 | 2.94 | 6.49 | 0.52 | 1.47 | 4.53 | 6.82 | 0.26 | −2.49 | 4.33 | 0.09 | −0.29 |
| Example 2 | | | | | | | | | | | | | | | |
| Comparative | Black ink | 12 | μm | 0.01 | −0.05 | 0.04 | 0.01 | −0.05 | 0.04 | 6.47 | 0.09 | −2.71 | 4.54 | 0.24 | −0.11 |
| Example 3 | | | | | | | | | | | | | | | |
| Comparative | paper | 380 | μm | 0.54 | 1.50 | 1.79 | 0.22 | 0.44 | 1.14 | 83.48 | −0.02 | −0.99 | 15.13 | −2.09 | 5.65 |
| Example 4 | | | | | | | | | | | | | | | |

In Comparative Example 2 in which a 6 μm-thick black ink layer was formed as the decorative layer, since light-shielding property by the decorative layer was insufficient, the transmittance Y was high and the light transmittance was over 0.5% even in a stacked body with a circular polarizing plate. In order to realize sufficient light-shielding property by a decorative layer using black ink, it was necessary to form the decorative layer with a thickness of 10 μm or more as demonstrated in Comparative Example 3.

In Examples 1 to 3 in which a metal thin-film (light reflection layer) was disposed as the decorative layer, the decorative layer had high light-shielding property even though the thickness of the decorative layer was as small as 120 nm. The films of Examples 1 to 3 showed a high reflectance Y due to the light reflection by the metal thin-film, but the reflectance of the stacked body with the circular polarizing plate was equivalent to Examples 1 and 2 in which the decorative layer formed of the black ink was provided. It can be understood that a″ and b″ of the reflected light approach 0 by stacking with the circular polarizing plate and hues of the reflected light were neutralized.

In Comparative Example 1 in which a 120 nm-thick silicon layer was disposed as the decorative layer, since silicon has a high refractive index and thus light reflection is fixed-end reflection, the reflectance of the stacked body with the circular polarizing plate was low. However, since silicon has light-shielding property lower than that of metal, transmittance of the stacked body with the circular polarizing plate exceeded 10%.

In Comparative Example 4, the white paper had a high reflectance equivalent to that of the metal layer, but since the light reflection on the front surface of the white paper was not fixed-end reflection, the reflectance of the stacked body with the circular polarizing plate was high, and the black appearance could not be realized.

From the above results, it can be understood that the thickness of the decorative pattern forming portion is small and excellent light-shielding property and excellent appearance can be realized by stacking a circular polarizing plate and a light reflection layer that performs fixed-end reflection.

### DESCRIPTION OF REFERENCE SIGNS

20 circular polarizing plate
21 polarizer
22 quarter wave plate
25 light reflection layer
28, 29 light reflection layer-equipped circular polarizing plate
30 cover window
40 touch panel
41 transparent substrate
42 transparent conductive layer
43 lead-out wiring
45, 55 flexible printed circuit
71, 72, 73 pressure sensitive pressure sensitive adhesive layer
103, 104, 105 image display device

1. An optical member comprising:
a circular polarizing plate having a first principal surface and a second principal surface; and
a patterned light reflection layer having a first principal surface and a second principal surface,
wherein
the first principal surface of the circular polarizing plate and the second principal surface of the light reflection layer are arranged so as to face each other,
the circular polarizing plate is configured such that light incident from a second principal surface-side to a first principal surface-side is emitted as circular polarized light, and
the light reflection layer has a light-shielding property, and is configured to reflect light from a circular polarizing plate-side with fixed-end reflection on the second principal surface of the light reflection layer.

2. The optical member according to claim 1, wherein the light reflection layer includes a metal layer.

3. The optical member according to claim 1, wherein the light reflection layer has a thickness of 3 μm or less.

4. The optical member according to claim 1, wherein the light reflection layer is integrally stacked with the circular polarizing plate directly or via another layer.

5. The optical member according to claim 1, further comprising a touch panel arranged on a first principal surface-side of the light reflection layer.

6. The optical member according to claim 1, wherein the light reflection layer has a frame-like pattern.

7. An image display device comprising:
a circular polarizing plate having a first principal surface and a second principal surface;
a patterned light reflection layer having a first principal surface and a second principal surface; and
an image display panel,
wherein
the first principal surface of the circular polarizing plate and the second principal surface of the light reflection layer are arranged so as to face each other, and the image display panel is arranged on a first principal surface-side of the light reflection layer,
the circular polarizing plate is configured to emit, as circular polarized light, light incident from a second principal surface-side to a first principal surface-side, and
the light reflection layer has a light-shielding property, and is configured to reflect light from a circular polarizing plate-side with fixed-end reflection on the second principal surface of the light reflection layer.

8. The image display device according to claim 7, further comprising a touch panel arranged between the light reflection layer and the image display panel.

9. The image display device according to claim 7, further comprising a cover window on the second principal surface of the circular polarizing plate, wherein the cover window includes a transparent resin substrate or a glass substrate

10. The image display device according to claim 7, wherein the image display panel is an organic EL panel.
